(19) United States
(12) Patent Application Publication
(10) Pub. No.: US 2015/0053943 A1
(43) Pub. Date: Feb. 26, 2015

(54) ORGANIC LIGHT EMITTING DIODE DISPLAY AND METHOD FOR MANUFACTURING THE SAME

(71) Applicant: Samsung Display Co., Ltd., Yongin-City (KR)

(72) Inventors: Jong-Hwan CHO, Yongin-City (KR); Hyeon-Deuk HWANG, Yongin-City (KR)

(73) Assignee: Samsung Display Co., Ltd, Yongin-City (KR)

(21) Appl. No.: 14/293,486

(22) Filed: Jun. 2, 2014

(30) Foreign Application Priority Data
Aug. 23, 2013 (KR) 10-2013-0100576

(51) Int. Cl. H01L 27/32; H01L 51/52

(52) U.S. Cl. CPC H01L 27/323; H01L 27/3244; H01L 51/5246
USPC 257/40; 438/26

(57) ABSTRACT

An organic light emitting diode device includes a display panel; a polarizing plate on the display panel; a first pressure adhesive layer between the display panel and the polarizing plate; a touch panel on the polarizing plate; a second pressure adhesive layer between the polarizing plate and the touch panel; a window on the touch panel; and a third pressure adhesive layer between the touch panel and the window.

This application claims priority to Korean Patent Application No. 10-2013-0100576 filed on Aug. 23, 2013, and all the benefits accruing therefrom under 35 U.S.C. §119, the entire contents of which are incorporated herein by reference.

### BACKGROUND

(a) Field

The invention relates to an organic light emitting diode (“OLED”) display and a manufacturing method thereof.

(b) Description of the Related Art

A display device is a device displaying an image, and a display device including an OLED is receiving attention.

Since the OLED has a self-light emitting characteristic such that a display device does not employ a separate light source, unlike a liquid crystal display, a thickness and weight of the entire display device may be reduced to improve a flexible characteristic of the display device. Further, the OLED display has high-quality characteristics such as low power consumption, high luminance and high reaction speed.

In general, the display device includes a display panel displaying images, an optical unit positioned on the display panel and including a polarizing plate, and a window positioned on the optical unit and protecting the optical unit.

Currently, the window has been developed to have a curved surface, and the display device has the flexible characteristic such that the display device is bent to be attached to the curved surface of the window and also has a curved surface.

### SUMMARY

Accordingly, one or more exemplary embodiment of the invention provides an organic light emitting diode (“OLED”) display in which separation of a display device from a window is minimized by minimizing a repulsive force of the display device with respect to other elements, and a manufacturing method thereof.

An OLED display according to the invention includes: a display panel; a polarizing plate on the display panel; a first pressure adhesive layer between the display panel and the polarizing plate; a touch panel on the polarizing plate; a second pressure adhesive layer between the polarizing plate and the touch panel; a window on the touch panel; and a third pressure adhesive layer between the touch panel and the window.

The first to third pressure adhesive layers may each include a material which maintains adhesion at a predetermined pressure.

The first to third pressure adhesive layers may each include an acryl-containing material having an ester polarity group, and the acryl-containing material may include acrylic acid ester or methacrylic acid ester as a main component.

The first to third pressure adhesive layers may each include polyvinyl ether or an ethylene/vinyl acetate copolymer.

An edge portion of the window may be curved, and the display panel, the polarizing plate and the touch panel may be curved according to the curved edge portion of the window.

A manufacturing method of an OLED display according to the invention includes: preparing a window having a curved edge portion, and a plate-type organic light emitting diode display member including a pressure adhesive layer thereon; aligning the window on the pressure adhesive layer; performing a first autoclave process to adhere the plate-type organic light emitting diode display member to the window; aligning a display panel to the plate-type organic light emitting diode display member; and performing a second autoclave process to adhere the plate-type organic light emitting diode display member to the display panel.

The plate-type organic light emitting diode display member may include at least one of a touch panel and a polarizing plate.

The preparing the plate-type organic light emitting diode display member may include: preparing the polarizing plate including a pressure adhesive layer on opposing surfaces thereof and the touch panel including a pressure adhesive layer on one surface thereof, and adhering one pressure adhesive layer of the polarizing plate and the touch panel to each other.

The first and secondary autoclave processes may be performed at a temperature of about 60 degrees Celsius (° C.) for about 30 minutes.

The pressure adhesive layer may include a material which maintains adhesion at a predetermined pressure.

A manufacturing method of an OLED display according to the invention includes: preparing a plate-type organic light emitting diode display member, preparing a window including a curved edge portion; and adhering the window and the plate-type organic light emitting diode display member through an autoclave process. The window and the plate-type organic light emitting diode display member are adhered to each other by a pressure adhesive layer, and the plate-type organic light emitting diode display member includes a touch panel, a polarizing plate or a display panel.

The plate-type organic light emitting diode display member may be adhered to the window, to be curved along the curved edge portion of the window.

The plate-type organic light emitting diode display member may be adhered to the window in a sequence of the touch panel, the polarizing plate and the display panel, and the pressure adhesive layer may be disposed between the window and the touch panel, between the touch panel and the polarizing plate, and between the polarizing plate and the display panel.

The autoclave process may be performed at a temperature of about 60° C. for about 30 minutes.

The pressure adhesive layer may include a material which maintains adhesion at a predetermined pressure.

According to one or more exemplary embodiment of the invention, by forming the pressure adhesive layer, when adhering the display panel to the window having the curved portion, the repulsive force of the display panel with respect to other OLED plate-type display elements may be minimized such that a separation of the window and the display panel may be minimized or effectively prevented.

### BRIEF DESCRIPTION OF THE DRAWINGS

The above and other features of this disclosure will become more apparent by describing in further detail exemplary embodiments thereof with reference to the accompanying drawings, in which:

FIG. 1 is a schematic cross-sectional view of an exemplary embodiment of an organic light emitting diode (“OLED”) display according to the invention.

FIG. 2 is an equivalent circuit diagram of an exemplary embodiment of one pixel of a display panel according to the invention.

FIG. 3 is a cross-sectional view of the one pixel shown in FIG. 2.

FIG. 4 to FIG. 6 are flowcharts detailing exemplary embodiments for manufacturing an OLED display according to the invention.

### DETAILED DESCRIPTION

The invention will be described more fully hereinafter with reference to the accompanying drawings, in which exemplary embodiments of the invention are shown. As those skilled in the art would realize, the described exemplary embodiments may be modified in various different ways, all without departing from the spirit or scope of the invention.

In order to clearly describe the invention, portions that are not connected with the description will be omitted. Like reference numerals designate like elements throughout the specification.

In addition, the size and thickness of each configuration shown in the drawings are arbitrarily shown for better understanding and ease of description, but the invention is not limited thereto.

In the drawings, the thickness of layers, films, panels, regions, etc., are exaggerated for clarity. In addition, in the drawings, for better understanding and ease of description, the thicknesses of some layers and areas are exaggerated. It will be understood that when an element such as a layer, film, region, or substrate is referred to as being “on” another element or layer, it can be directly on the other element or intervening elements may also be present. In contrast, when an element is referred to as being “directly on” another element or layer, there are no intervening elements or layers present. As used herein, connected may refer to elements being physically and/or electrically connected to each other. As used herein, the term “and/or” includes any and all combinations of one or more of the associated listed items.

It will be understood that, although the terms first, second, third, etc., may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of the invention.

In addition, unless explicitly described to the contrary, the word “comprise” and variations such as “comprises” or “comprising” will be understood to imply the inclusion of stated elements but not the exclusion of any other elements. The terminology used herein is for the purpose of describing particular embodiments only and is not intended to be limiting of the invention. As used herein, the singular forms “a,” “an” and “the” are intended to include the plural forms as well, unless the context clearly indicates otherwise.

Further, in the specification, the word “on” means positioning on or below the object portion, but does not essentially mean positioning on the upper side of the object portion based on a gravity direction.

Embodiments of the invention are described herein with reference to cross-section illustrations that are schematic illustrations of idealized embodiments (and intermediate structures) of the invention. As such, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10%, 5% of the stated value.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

All methods described herein can be performed in a suitable order unless otherwise indicated herein or otherwise clearly contradicted by context. The use of any and all examples, or exemplary language (e.g., “such as”), is intended merely to better illustrate the invention and does not pose a limitation on the scope of the invention unless otherwise claimed. No language in the specification should be construed as indicating any non-claimed element as essential to the practice of the invention as used herein.

Hereinafter, the invention will be described in detail with reference to the accompanying drawings.

Now, an organic light emitting diode (“OLED”) display according to the invention will be described with reference to accompanying drawings.

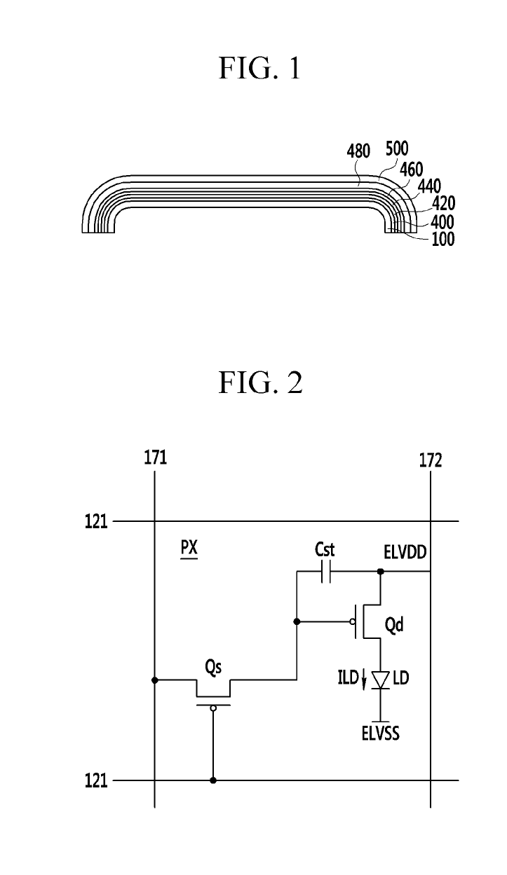

FIG. 1 is a schematic cross-sectional view of an OLED display according to an exemplary embodiment.

As shown in FIG. 1, an OLED display according to the invention includes a display panel 100, a first pressure adhesive layer 400 positioned on the display panel 100, a polarizing plate 420 positioned on the first pressure adhesive layer 400, a second pressure adhesive layer 440 positioned on the polarizing plate 420, a touch panel 460 positioned on the second pressure adhesive layer 440, a third pressure adhesive layer 480 positioned on the touch panel 460, and a window 500 positioned on the third pressure adhesive layer 480.

The display panel 100 includes a plurality of pixels each including an organic light emitting element to display an image, and has a flexible characteristic.

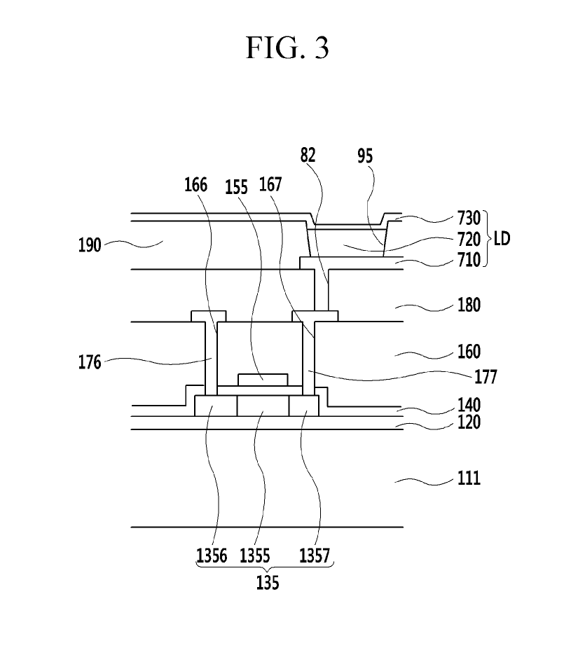

Next, an inner structure of one pixel in a display panel according to an exemplary embodiment will be described with reference to FIG. 2 and FIG. 3.

FIG. 2 is an equivalent circuit of an exemplary embodiment of one pixel of a display panel according to the invention.

As shown in FIG. 2, a display device includes a plurality of signal lines 121, 171 and 172, and a plurality of pixels PX connected thereto and arranged substantially in a matrix.

The signal lines include a plurality of gate lines 121 for transmitting a gate signal (or a scan signal), a plurality of data lines 171 for transmitting a data signal, and a plurality of driving voltage lines 172 for transmitting a driving voltage ELVDD. The gate lines 121 are elongated in a row direction and are substantially parallel with each other, and parts of the data lines 171 and the driving voltage lines 172 are elongated in a column direction which intersects the row direction and are substantially parallel with each other.

The pixel PX includes a switching thin film transistor Qs, a driving thin film transistor Qd, a storage capacitor Cst, and an organic light emitting diode (OLED) LD.

The switching thin film transistor Qs includes a control terminal, an input terminal and an output terminal. The control terminal is connected to the gate line 121, the input terminal is connected to the data line 171 and the output terminal is connected to a driving thin film transistor Qd. The switching thin film transistor Qs responds to the scan signal applied to the gate line 121 to transmit the data signal applied to the data line 171 to the driving thin film transistor Qd.

The driving thin film transistor Qd includes a control terminal, an input terminal, and an output terminal. The control terminal is connected to the switching thin film transistor Qs, the input terminal is connected to the driving voltage line 172, and the output terminal is connected to an OLED (or organic light emitting element) LD. The driving thin film transistor Qd outputs an output current ILD that is variable according to a voltage between the control terminal and the output terminal.

The capacitor Cst is connected between the control terminal and the input terminal of the driving thin film transistor Qd. The capacitor Cst charges the data signal applied to the control terminal of the driving thin film transistor Qd and maintains the data signal when the switching thin film transistor Qs is turned off.

The OLED LD includes an anode connected to the output terminal of the driving thin film transistor Qd and a cathode connected to a common voltage ELVSS. The OLED LD changes intensity and emits light depending on the output current ILD of the driving thin film transistor Qd to thus display the image.

An inter-layer structure of an OLED display according to an exemplary embodiment will now be described with reference to FIG. 3 as well as FIG. 2.

FIG. 3 is a cross-sectional view of the one pixel shown in FIG. 2 according to the invention.

The layered configuration of the driving transistor and the switching transistor of FIG. 2 is the same such that a driving transistor connected to the organic light emitting element will be described in FIG. 3.

As shown in FIG. 3, a buffer layer 120 is disposed on a substrate 111 of an OLED display according to the invention.

The substrate 111 may be a transparent insulating substrate including glass, quartz, ceramic or a polymer material, or the substrate 111 may be a metal substrate including stainless steel. The polymer material may be an organic material selected from insulating organic materials, such as polyether sulfone (“PES”), polyacrylate, polyetherimide (“PEI”), polyethylene naphthalate (“PEN”), polyethylene terephthalate (“PET”), polyphenylene sulfide (“PPS”), polyallylate, polyimide, polycarbonate (“PC”), cellulose triacetate (“TAC”), and cellulose acetate propionate (“CAP”).

The buffer layer 120 may have a single film structure including a silicon nitride (SiNx), or may have a multilayer structure formed by stacking a silicon nitride (SiNx) and a silicon oxide (SiOₓ) film or layer. The buffer layer 120 reduces or effectively prevents permeation of undesired components such as impurities or moisture, to the OLED, and planarizes a surface of the layered structure of the OLED display.

A semiconductor 135 including polysilicon is disposed on the buffer layer 120.

The semiconductor 135 includes a channel region 1355, and a source region 1356 and a drain region 1357 respectively disposed on opposing sides of the channel region 1355. The channel region 1355 of the semiconductor 135 includes polysilicon to which an impurity is not doped, that is, an intrinsic semiconductor. The source region 1356 and the drain region 1357 of the semiconductor 135 include polysilicon to which a conductive impurity is doped, that is, an impurity semiconductor.

The source region 1356 and the drain region 1357 can include one of a p-type impurity and an n-type impurity.

A gate insulating layer 140 is disposed on the semiconductor 135. The gate insulating layer 140 may have a single layer structure including tetraethyl orthosilicate (“TEOS”), a silicon oxide (SiOₓ) or a silicon nitride (SiNx), or may include a multilayer structure formed by stacking a silicon oxide (SiOₓ) and a silicon nitride (SiNx) film or layer.

A gate electrode 155 of the driving transistor is disposed on the gate insulating layer 140. The gate electrode 155 at the control terminal of the driving transistor is electrically connected to the drain electrode as the output terminal of the switching transistor, as illustrated in FIG. 2.

The gate electrode 155 may have a single layer or multiple layer structure including a low resistance material or a highly corrosion-resistant material such as Al, Ti, Mo, Cu, Ni and alloys thereof.

A first interlayer insulating layer 160 is disposed on the gate electrode 155.

The first interlayer insulating layer 160 may have a single layer or multiple layer structure including at least one of TEOS, a silicon nitride and a silicon oxide, similar to the structure of the gate insulating layer 140 described above.

A source contact hole 166 and a drain contact hole 167 are defined in the first interlayer insulating layer 160 and the gate insulating layer 140, and respectively expose the source region 1356 and the drain region 1357.

A source electrode 176 and a drain electrode 177 are disposed on the first interlayer insulating layer 160. The source electrode 176 is connected to the source region 1356 through the source contact hole 166, and the drain electrode 177 is connected to the drain region 1357 through the drain contact hole 167. The source electrode 176 as an input terminal of the driving transistor is connected to the driving voltage line 172, as illustrated in FIG. 2.

The source electrode 176 and the drain electrode 177 may have a single or multiple layer structure including a low resistance material or a highly corrosion-resistant material such as Al, Ti, Mo, Cu, Ni and alloys thereof. In one exemplary embodiment, for example, the source electrode 176 and drain electrode 177 include a tri-layer structure including Ti/Cu/Ti, Ti/Ag/Ti, or Mo/Al/Mo.

A second interlayer insulating layer 180 is disposed on the source electrode 176 and the drain electrode 177. A contact hole 82 is defined in the second interlayer insulating layer 180 and exposes the drain electrode 177 of the driving transistor.

A first electrode 710 electrically connected to the drain electrode 177 through the contact hole 82, is disposed on the second interlayer insulating layer 180.

The second interlayer insulating layer 180 may have a single layer or multiple layer structure including at least one of TEOS, a silicon nitride and a silicon oxide, similar to the first interlayer insulating layer 160 described above. Also, the second interlayer insulating layer 180 may include a low dielectric constant organic material.

The first electrode 710 may be the anode of the organic light-emitting element LD of FIG. 2. While the second interlayer insulating layer 180 is disposed between the first electrode 710 and the drain electrode 177 in the illustrated exemplary embodiment of the invention, the first electrode 710 may be disposed in a same layer as the drain electrode 177 and may be integrated with the drain electrode 177 to form a single, unitary, indivisible element.

A pixel definition layer 190 is disposed on the first electrode 710.

An opening 95 is defined in the pixel definition layer 190 and exposes the first electrode 710. The pixel definition layer 190 may include a resin such as a polyacrylate or a polyimide, or an inorganic material such as silica.

An organic emission layer 720 is disposed in the opening 95 of the pixel definition layer 190.

The organic emission layer 720 includes an emission layer and a charge auxiliary layer. The charge auxiliary layer may include at least one of a hole transport layer (“HTL”), a hole-injection layer (“HIL”), an electron transport layer (“ETL”), and an electron injection layer (“EIL”).

In an exemplary embodiment where the organic emission layer 720 includes all of the aforementioned layers of the charge auxiliary layer, the HIL may be disposed on the first electrode 710 that is the anode of the organic light emitting element LD, and the HTL, the emission layer, the ETL, and the EIL may be sequentially laminated thereon.

A second electrode 730 is disposed on the pixel definition layer 190 and the organic emission layer 720.

The second electrode 730 becomes a cathode of the organic light emitting element LD. Accordingly, the first electrode 710, the organic emission layer 720 and the second electrode 730 form an organic light emitting element LD.

The organic light emitting element LD can be one of a front display type, a rear display type and a dual-sided display type according to the direction in which the organic light emitting element LD emits light.

In the exemplary embodiment of the front display type, the first electrode 710 includes a reflective layer and the second electrode 730 includes a transflective or transmissive layer. In an exemplary embodiment of the rear display type, the first electrode 710 includes a transflective layer and the second electrode 730 includes a reflective layer. In an exemplary embodiment of a dual-sided display type, the first electrode 710 and the second electrode 730 include a transparent layer or a transflective layer.

The reflective layer and the semi-transparent layer include at least one of Mg, Ag, Au, Ca, Li, Cr, and Al, and an alloy thereof. The reflective layer and the transflective layer are determined by cross-sectional thicknesses thereof. The reflective and/or the transflective layer may have a cross-sectional thickness of less than about 200 nanometers (nm). While the transmittance of the reflective layer or transflective layer increases as the cross-sectional thickness thereof decreases, the resistance thereof increases when the layer is excessively thin.

The transmissive layer may include at least one of indium tin oxide (“ITO”), indium zinc oxide (“IZO”), zinc oxide (“ZnO”) and indium oxide (In2O3).

Again referring to FIG. 1, the first to third pressure adhesive layers 400, 440 and 480 may include a material maintaining adhesion when a predetermined pressure is applied at room temperature, and may have a low Young's modulus and a glass transition temperature of a relatively low temperature.

The first to third pressure adhesive layers 400, 440 and 480 as an acryl-based adhesive such as an acryl-containing material which has an ester polarity group. In one exemplary embodiment, for example, The acryl-containing material may be a material including a main component such as an acrylic acid ester and a methacrylic acid ester. Further, the adhesive may be polyvinyl ether or an ethylene/vinyl acetate copolymer.

The polarizing plate 420 to improve contrast and visibility of the OLED display may include a circular polarizing plate and/or a linear polarizing plate.

In the touch panel 460 for touch sensing, first sensing (“Tx”) wires and second sensing (“Rx”) wires cross and are insulated from each other. In the touch panel 460 including the Rx wires and the Tx wires as a capacitive type of touch panel, if a touch voltage is applied to the Rx wire and the Tx wire that are crossed and any one position is touched through an input means such as a finger or a pen, a voltage drop is generated thereby determining position coordinates.

The window 500 may have a single layer or a multi-layer structure including at least one of PC, polymethyl methacrylate (“PMMA”), polyarylate (“PAR”), PES, PET and PEN.

The window 500 include glass or a heat cured elastomer such as Silplus®, is provided to the outermost part of the OLED display, and protects the display panel of the OLED display from external scratches and impacts. An edge portion of the window 500 is curved, thereby forming a shape enclosing elements of the OLED display including the display panel 100, the touch panel 460, etc.

The display panel 100, the touch panel 460 and the polarizing plate 420 are attached to an inner surface of the window 500 such that the display panel 100, the touch panel 460 and the polarizing plate 420 may have a curved portion according to an inner shape of the window 500.

In contrast, the first to third pressure adhesive layers 400, 440 and 480 as the material having adhesion based on the pressure applied thereto, each have a cross-sectional thickness of about 5 micrometers (μm) to about 100 μm which is thinner than a conventional adhesive layer. Since the first to third pressure adhesive layers 400, 440 and 480 each have a cross-sectional thickness which is smaller than a conventional adhesive layer, a repulsive force may be minimized at the curved potion thereof.

That is, in the OLED display according to the invention, the display panel 100, the touch panel 460 and the polarizing plate 420 of the plate type (e.g., relatively thin and uniform thickness) are each attached to the inner surface of the window 500 having the curved edge by using a respective pressure adhesive layer such that the edge portion thereof is bent according to the curved inner surface of the window 500.

When a cross-sectional thickness of the display panel 100, the touch panel 460 and the polarizing plate 420 that are respectively connected to each other by an adhesive layer is relatively large, the repulsive force of the display panel, the touch panel and the polarizing plate that are positioned at opposing sides with respect to the adhesive layer is increased. However, in one or more exemplary embodiment of the invention, the cross-sectional thickness of the adhesive layer is reduced such that the repulsive force of the display panel 100, the touch panel 460 and the polarizing plate 420 that are connected to each other by the adhesive layers may be minimized.

Also, in one or more exemplary embodiment of the invention, when the pressure adhesive layer including the material having adhesion based on the pressure applied thereto is used in forming an OLED display, a manufacturing process of the OLED display may be simplified.

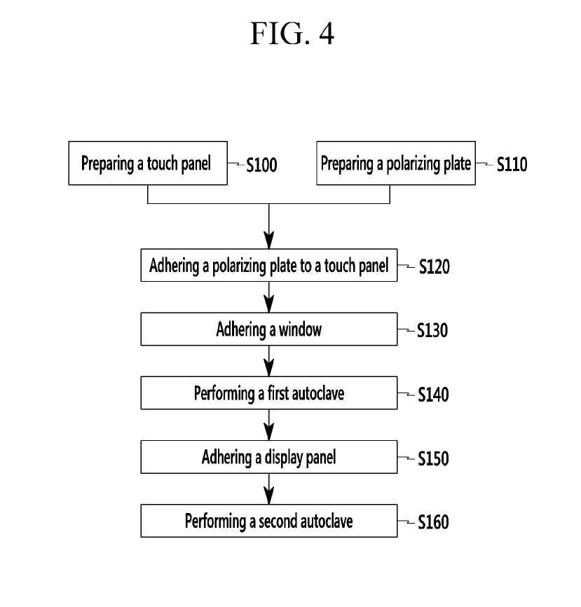

Next, exemplary embodiments of methods of manufacturing the OLED display of FIG. 1 will be described with reference to FIGS. 4 to 6 as well as FIG. 1.

FIG. 4 to FIG. 6 are flowcharts detailing exemplary embodiments for manufacturing an OLED display according to the invention.

In one exemplary embodiment of a method of manufacturing an OLED display, referring to FIGS. 1 and 4, the touch panel 460 and the polarizing plate 420 are respectively prepared (S100 and S110). The polarizing plate 420 is attached to the touch panel 460 (S120), the window 500 is attached to the touch panel 460 (S130), a first autoclave process is performed (S140), the display panel 100 is attached to the polarizing plate 420 (S150), and a second autoclave process is performed (S160), thereby completing the OLED display.

In S100 and S110 respectively preparing the touch panel 460 and the polarizing plate 420, the touch panel 460 including the pressure adhesive layer 480 on one surface thereof is prepared and the polarizing plate 420 including the pressure adhesive layers 400 and 440 on opposing surfaces thereof is prepared.

When the touch panel 460 and the polarizing plate 420 are combined after the respective preparation thereof, a protection film (not shown) is formed on the pressure adhesive layers of the touch panel 460 and the polarizing plate 420, such that the combination of elements is performed after removing the respective protection film.

An opposing other surface of the touch panel 460 on which the pressure adhesive layer 480 is not formed, is disposed on a pressure adhesive layer 440 of the polarizing plate 420 and is pressed to be adhered thereto (S120). The adhesion is performed by using the pressure adhesive layer 440 such that the adhesion may be easily performed at a predetermined pressure applied thereto.

In S130 including adhering the window 500 to the touch panel 460, the window 500 is disposed at the one surface of the touch panel 460 on which the pressure adhesive layer 480 is formed, is aligned through vacuum combination, and then the first autoclave process is performed for the adhesion (S140).

The first autoclave process is performed at a temperature of about 60 degrees Celsius (° C.) for about 30 minutes, and accordingly, the touch panel 460 and the polarizing plate 420 of the plate type are easily bent according to the curved part of the window 500 to be well adhered to the inner surface of the window 500.

The display panel 100 is aligned to the pressure adhesive layer 400 formed at the other surface of the polarizing plate 420 on which the touch panel 460 is not formed (S150), and the second autoclave process is performed for the adhesion (S160). The second autoclave process is also performed with the same process as the first autoclave process, such that the edge portion of the display panel 100 of the plate type may be well adhered to the touch panel 460 having the edge bent according to the inner surface of the window 500.

In an exemplary embodiment of the invention, the pressure adhesive layer includes material having adhesion based on the pressure applied thereto is included in the OLED display such that the repulsive force of elements of the OLED display is minimized, thereby easily adhering the display panel, the polarizing plate and the touch panel to each other to form the OLED display.

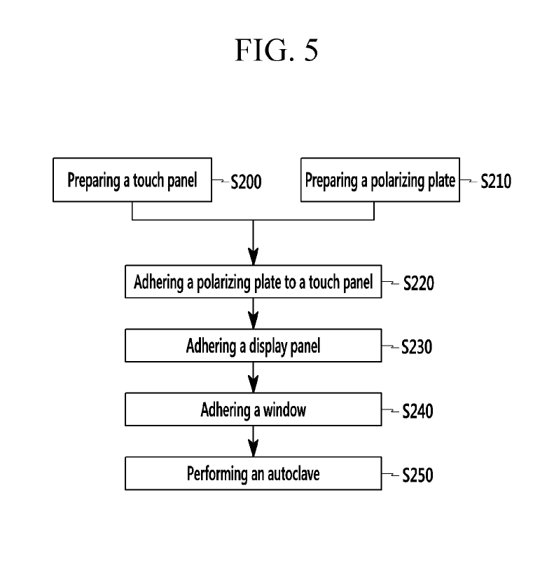

In another exemplary embodiment of a method of manufacturing an OLED display, referring to FIG. 1 and FIG. 5, the touch panel 460 and the polarizing plate 420 are respectively prepared (S200 and S210). The polarizing plate 420 is adhered to the touch panel 460 (S220), the display panel 100 is adhered to the touch panel 460 (S230), the window 500 is aligned with the touch panel 460 (S240), and the autoclave process is performed (S250) to complete the OLED display.

The touch panel 460 includes the pressure adhesive layer 480 formed on one surface thereof, and the polarizing plate 420 includes the pressure adhesive layers 400 and 440 formed on opposing surfaces thereof.

In the manufacturing method of the OLED display of FIG. 5, differently from FIG. 4, like the touch panel 460, the polarizing plate 420 and the display panel 100, each of the plate-type members 100 420 and 460 are deposited and adhered to each other, and then the window 500 is adhered after combining the plate-type members 100, 420 and 460.

That is, by adhering the window 500 after depositing and combining the plate-type members 100, 420 and 460 that are capable of being adhered to each other only by pressure, the autoclave process to adhere each plate-type member to the window may be performed only one time.

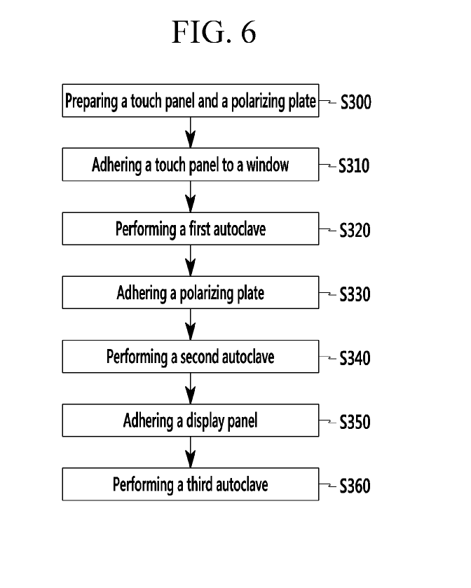

In still another exemplary embodiment of a method of manufacturing an OLED display, referring to FIG. 1 and FIG. 6, the touch panel 460 and the polarizing plate 420 are respectively prepared (S300). The touch panel 460 is adhered to the window 500 (S310), the first autoclave process is performed (S320), the polarizing plate 420 is adhered to the touch panel 460 (S330), the second autoclave process is performed (S340), the display panel 100 is adhered to the polarizing plate 420 (S350), and the third autoclave process is performed (S360), thereby completing the OLED display.

The touch panel 460 includes the pressure adhesive layer 480 formed on one surface thereof, and the polarizing plate 420 includes the pressure adhesive layers 400 and 440 formed on opposing surfaces thereof.

In the manufacturing method of the OLED display of FIG. 6, differently from the manufacturing method of FIG. 4 and FIG. 5, the plate-type members such as the touch panel 460, the polarizing plate 420 and the display panel 100 are sequentially adhered to the window 500.

In this way, an autoclave process must be performed for each combination of plate-type member to the OLED display structure previously formed, to sequentially adhere the plate-type members to the window 500.

In the manufacturing method of FIG. 4 and FIG. 5, the window is adhered after adhering at least two members among the plate-type members of the OLED display, such that the number of the autoclave processes may be reduced compared with the manufacturing method of FIG. 6. However, as the number of plate-type elements of the OLED display increases in the structure, an overall cross-sectional thickness of the OLED display structure becomes greater such that the repulsive force between elements may be increased compared with FIG. 6.

That is, in one or more exemplary embodiment of an OLED display according to the invention, separation of the display panel from the window by a repulsive force of the display panel, may be reduced or effectively prevented.

While this invention has been described in connection with what is presently considered to be practical exemplary embodiments, it is to be understood that the invention is not limited to the disclosed exemplary embodiments, but, on the contrary, is intended to cover various modifications and equivalent arrangements included within the spirit and scope of the appended claims.

What is claimed is:

1. An organic light emitting diode display comprising:
a display panel;
a polarizing plate on the display panel;
a first pressure adhesive layer between the display panel and the polarizing plate;
a touch panel on the polarizing plate;
a second pressure adhesive layer between the polarizing plate and the touch panel;
a window on the touch panel; and
a third pressure adhesive layer between the touch panel and the window.

2. The organic light emitting diode display of claim 1, wherein
the first to third pressure adhesive layers each comprise a material which maintains adhesion at a predetermined pressure.

3. The organic light emitting diode display of claim 2, wherein
the first to third pressure adhesive layers each comprise an acryl-containing material having an ester polarity group.

4. The organic light emitting diode display of claim 3, wherein
the acryl-containing material comprises an acrylic acid ester or a methacrylic acid ester as a main component.

5. The organic light emitting diode display of claim 2, wherein
the first to third pressure adhesive layers each comprise polyvinyl ether or an ethylene/vinyl acetate copolymer.

6. The organic light emitting diode display of claim 1, wherein
an edge portion of the window is curved, and
the display panel, the polarizing plate and the touch panel are curved according to the curved edge portion of the window.

7. A method of manufacturing an organic light emitting diode display, comprising:
preparing a window having a curved edge portion, and a plate-type organic light emitting diode display member comprising a pressure adhesive layer thereon;
aligning the window on the pressure adhesive layer;
performing a first autoclave process to adhere the plate-type organic light emitting diode display member to the window;
aligning a display panel to the plate-type organic light emitting diode display member; and
performing a second autoclave process to adhere the plate-type organic light emitting diode display member to the display panel.

8. The method of claim 7, wherein
the plate-type organic light emitting diode display member comprises at least one of a touch panel and a polarizing plate.

9. The method of claim 8, wherein
the preparing the plate-type organic light emitting diode display member comprises:
preparing the polarizing plate comprising a pressure adhesive layer on opposing surfaces thereof and the touch panel comprising a pressure adhesive layer on one surface thereof, and
adhering one pressure adhesive layer of the polarizing plate and the touch panel to each other.

10. The method of claim 7, wherein
the first and second autoclave processes are performed at a temperature of about 60 degrees Celsius for about 30 minutes.

11. The method of claim 7, wherein
the pressure adhesive layer comprises a material which maintains adhesion at a predetermined pressure.

12. A method of manufacturing an organic light emitting diode display, comprising:
preparing a plate-type organic light emitting diode display member,
preparing a window comprising a curved edge portion; and
adhering the window and the plate-type organic light emitting diode display member through an autoclave process,
wherein
the window and the plate-type organic light emitting diode display member are adhered to each other by a pressure adhesive layer, and
the plate-type organic light emitting diode display member comprises a touch panel, a polarizing plate or a display panel.

13. The method of claim 12, wherein
the plate-type organic light emitting diode display member is adhered to the window, to be curved along the curved edge portion of the window.

14. The method of claim 12, wherein
the plate-type organic light emitting diode display member is adhered to the window in a sequence of the touch panel, the polarizing plate and the display panel, and
the pressure adhesive layer is disposed between the window and the touch panel, between the touch panel and the polarizing plate, and between the polarizing plate and the display panel.

15. The method of claim 12, wherein
the autoclave process is performed at a temperature of about 60 degrees Celsius for about 30 minutes.

16. The method of claim 12, wherein
the pressure adhesive layer comprises a material which maintains adhesion at a predetermined pressure.
